(19) United States
(12) Patent Application Publication
(10) Pub. No.: US 2002/0084487 A1
(43) Pub. Date: Jul. 4, 2002

(54) Semiconductor device

(76) Inventor: Hiroaki Takasu, Chiba-shi (JP)

Correspondence Address: ADAMS & WILKS, 31st Floor, 50 Broadway, New York, NY, 10004, US

(21) Appl. No.: 09/975,844

(22) Filed: Oct. 12, 2001

(30) Foreign Application Priority Data
Oct. 13, 2000 (JP) 2000-313775

(51) Int. Cl. H01L 27/01

(52) U.S. Cl. 257/347

(57) ABSTRACT

A semiconductor device in which analog ICs are formed having a mixture of complete depletion high speed MOS transistors and high endurance MOS transistors on an SOI substrate, and which is strong with respect to ESD destruction, is provided. A laser trimming position determining pattern is constituted of a region having high light reflectivity and a region having low light reflectivity. The high light reflectivity region is formed by a high light reflectivity film on a level base, and the low light reflectivity region is formed by the high light reflectivity film formed on a lattice pattern, a stripe pattern, or a dot pattern for diffused reflection of light, which is formed of the same polycrystalline silicon film as a laser trimming fuse element.

### BACKGROUND OF THE INVENTION

1. Field of the Invention

The present invention relates to a semiconductor device having a semiconductor integrated circuit formed on an SOI substrate.

2. Description of the Related Art

Semiconductor integrated circuits formed on SOI substrates are widely known at present. In particular, high speed MOS transistors have superior properties compared to MOS transistors formed on conventional silicon substrates because they use complete depletion modes.

In addition, laser trimming methods for controlling analog properties are known in analog semiconductor integrated circuit devices. For example, the method is disclosed in Japanese Patent Application Laid-open No. Hei 5-13670. After two dimensional patterning of integrated circuits on a semiconductor wafer, the electrical properties of each integrated circuit are measured in a wafer state. Next, in order to regulate the analog properties, a fuse element formed in a portion of a wiring is selected, and cut by laser beam irradiation. The analog properties of the integrated circuit can be matched to the desired properties by cutting selection of the fuse element in accordance with the laser trimming method. A position determining pattern is formed in the bare semiconductor wafer surface in order to irradiate a laser beam to a predetermined fuse element. FIG. 2A is a planar diagram of a conventional position determining pattern, FIG. 2B is a cross sectional diagram of a conventional position determining pattern, and FIG. 2C is a diagram showing changes in the amount of light reflected when the position determining pattern is scanned along a line segment B-B′ by light beam irradiation. The conventional position determining patterns have a first insulating film 102 made from a silicon oxide film formed on a silicon substrate 101, and a second insulating film 104 made from a film such as a PSG film as an outer portion. A square aluminum film 105 is arranged on the inside of the outer portion. If a light beam is scanned along the B direction of FIG. 2A, then a light reflection pattern like that of FIG. 2C is obtained because the reflectivity of the aluminum film 105 is high. The positional relationship between the position determining pattern and the fuse element made from a polycrystalline silicon film of the integrated circuit has been determined in design. Predetermined coordinates of the fuse elements can therefore be determined by detecting the position determining pattern by light beam irradiation, and the fuse elements can be selectively trimmed by laser irradiation in those locations.

However, if the complete depletion mode is used with conventional semiconductor integrated circuit formed on SOI substrate, then the thickness of a single crystal silicon device formation layer formed on the SOI substrate through an embedded oxide film must be equal to or less than 1000 angstroms, and it is difficult to form high endurance elements, or ESD protecting elements for preventing ESD destruction (static destruction) on the thin single crystal silicon device formation layer.

Furthermore, in conventional semiconductor integrated circuit formed on SOI substrate, consideration of scribing is not made. Thus, there are cases in which defects such as cracks and fragmentation develop in a dicing process for cutting out IC chips.

Not limited to ICs formed on SOI substrates, the formation of fuse elements by using polycrystalline silicon films is also generally known. The fuse elements and the position determining pattern are formed by different thin films in laser trimming, and therefore accurate position determination can be performed. If the position determining pattern is detected by the aluminum pattern, and the fuse element polycrystalline silicon film is laser trimmed, then there is a position shift of a laser irradiation region 32 with respect to a fuse element 31, as shown in FIG. 8. The laser irradiation region 32 has an energy distribution which becomes a Gaussian distribution, and therefore the energy strength of a laser irradiation edge portion is low. Consequently, if there is a large alignment slip between the polycrystalline silicon film patterning and the aluminum film patterning during wafer processing, then a problem develops in that the fuse elements cannot be stably cut. Note that reference numeral 33 denotes a burning of the base, and reference numeral 34 denotes a portion that becomes a fuse cut remnant.

Further, with analog ICs such as voltage detectors, breeder resistors made from a plurality of polycrystalline silicon resistors are often used. However, in the polycrystalline silicon resistors, it is difficult to obtain identical resistance values due to influence of the grain, and this becomes a hindrance to producing high precision analog ICs.

### SUMMARY OF THE INVENTION

An object of the present invention is to provide a semiconductor device, on which high precision analog ICs having a mixture of complete depletion high speed MOS transistors and high endurance MOS transistors are formed on an SOI substrate, which is strong with respect to ESD destruction, with a form in which factors such as broken fragments due to a dicing process are prevented.

In addition, an object of the present invention is to make fuse element regions smaller and to reduce costs by increasing the trimming position determining precision.

The present invention uses the following means in order to resolve the above problems.

(1) The following are formed in a semiconductor integrated circuit formed on an SOI substrate: a laser trimming fuse element; a laser trimming position determining pattern; a complete depletion high speed MOS transistor; a high endurance MOS transistor; an ESD protecting element; and a breeder resistor formed by a plurality of resistors.

(2) With the semiconductor device described in (1) above:

the laser trimming position determining pattern is constituted of a region having high light reflectivity and a region having low light reflectivity;

the high light reflectivity region is formed by a high light reflectivity film on a level base; and

the low light reflectivity region is formed by the high light reflectivity film formed on a lattice pattern, a stripe pattern, or a dot pattern for diffused reflection of light, which is structured by the same thin film as the laser trimming fuse element.

(3) The laser trimming fuse element is formed of a polycrystalline silicon film in the semiconductor device described in (1) above.

(4) A polycrystalline silicon film forming the laser trimming fuse element is the same film as a gate electrode of the complete depletion high speed MOS transistor and a gate electrode of the high endurance MOS transistor in the semiconductor device described in (1) above.

(5) The complete depletion high speed MOS transistor is formed in a single crystal silicon device formation layer, and the high endurance MOS transistor and the ESD protecting element are formed on a silicon substrate remaining after the single crystal silicon device formation layer and an embedded oxide film are removed from the SOI substrate with the semiconductor device described in (1) above.

(6) In semiconductor device described in (1) above, the breeder resistor is formed by the single crystal silicon device formation layer.

(7) A single crystal silicon device formation layer and an embedded oxide film are removed in scribe regions of the semiconductor integrated circuit with the semiconductor device described in (1) above.

### BRIEF DESCRIPTION OF THE DRAWINGS

In the accompanying drawings:

FIG. 1 is a schematic cross sectional diagram of a semiconductor device of the present invention;

FIG. 2A is a planar diagram of a pattern used for position determination in a conventional semiconductor device;

FIG. 2B is a cross sectional diagram of the pattern used for position determination in the conventional semiconductor device;

FIG. 2C is a diagram showing the amount of light reflected along a line segment B-B′ in FIG. 2A;

FIG. 3A is a planar diagram of a pattern used for position determination in a first embodiment of a semiconductor device of the present invention;

FIG. 3B is a cross sectional diagram of the pattern used for position determination in the first embodiment of the semiconductor device of the present invention;

FIG. 3C is a diagram showing the amount of light reflected along a line segment A-A′ in FIG. 3A;

FIG. 4A is a planar diagram of a pattern used for position determination in a second embodiment of a semiconductor device of the present invention;

FIG. 4B is a cross sectional diagram of the pattern used for position determination in the second embodiment of the semiconductor device of the present invention;

FIG. 4C is a diagram showing the amount of light reflected along a line segment C-C′ in FIG. 4A;

FIG. 5A is a planar diagram of a pattern used for position determination in a third embodiment of a semiconductor device of the present invention;

FIG. 5B is a cross sectional diagram of the pattern used for position determination in the third embodiment of the semiconductor device of the present invention;

FIG. 5C is a diagram showing the amount of light reflected along a line segment D-D′ in FIG. 5A;

FIG. 6A is a planar diagram of a pattern used for position determination in a fourth embodiment of a semiconductor device of the present invention;

FIG. 6B is a cross sectional diagram of the pattern used for position determination in the fourth embodiment of the semiconductor device of the present invention;

FIG. 6C is a diagram showing the amount of light reflected along a line segment E-E′ in FIG. 6A;

FIG. 7A is a planar diagram of a pattern used for position determination in a fifth embodiment of a semiconductor device of the present invention;

FIG. 7B is a cross sectional diagram of the pattern used for position determination in the fifth embodiment of the semiconductor device of the present invention;

FIG. 7C is a diagram showing the amount of light reflected along a line segment F-F′ in FIG. 7A;

FIG. 8 is a planar diagram of a fuse element of the conventional semiconductor device;

FIG. 9 is a planar diagram of a fuse element of the semiconductor device of the present invention; and

FIG. 10 is a block diagram of the semiconductor device of the present invention.

### DETAILED DESCRIPTION OF THE PREFERRED EMBODIMENTS

Embodiment Mode

A laser trimming fuse element; a laser trimming position determining pattern; a complete depletion high speed MOS transistor; a high endurance MOS transistor; an ESD protecting element; and a breeder resistor formed by a plurality of resistors are formed in a semiconductor integrated circuit constructed on an SOI substrate.

The laser trimming position determining pattern is constituted of a region having high light reflectivity, and a region having low light reflectivity. The high light reflectivity region is formed by a high light reflectivity film on a level base, and the low light reflectivity region is formed by the high light reflectivity film formed on a lattice pattern, a stripe pattern, or a dot pattern for diffused reflection of light, which is structured by the same thin film as the laser trimming fuse element.

The laser trimming fuse element and the breeder resistor are formed by a polycrystalline silicon device formation layer. The laser trimming fuse element is formed by the same polycrystalline silicon film as a gate electrode of the complete depletion high speed MOS transistor and a gate electrode of the high endurance MOS transistor.

Further, the complete depletion high speed MOS transistor is formed in a single crystal silicon device formation layer, and the high endurance MOS transistor and the ESD protecting element are formed on a silicon substrate remaining after the single crystal silicon device formation layer and an embedded oxide film are removed from the SOI substrate.

In addition, the single crystal silicon device formation layer and the embedded oxide film are removed in scribe regions of the semiconductor integrated circuit.

A semiconductor device, on which high precision analog ICs having a mixture of complete depletion high speed MOS transistors and high endurance MOS transistors are formed on an SOI substrate, which is strong with respect to ESD destruction, with a form in which factors such as broken fragments due to a dicing process are prevented, can thus be provided.

In particular, the pattern used for determining the laser trimming position is constituted of the region of high light reflectivity and the region of low light reflectivity. The high light reflectivity region is formed by the high light reflectivity film formed on the level base, while the low light reflectivity region is formed by the high light reflectivity film formed on the lattice pattern, the stripe pattern, or the dot pattern for diffused reflection of light, which is structured by the same polycrystalline silicon device formation layer as the laser trimming fuse element. The interface between the high light reflectivity region and the low light reflectivity region, namely, the location at which the light reflectivity changes suddenly, is therefore prescribed by the pattern formed by the same single crystal silicon device formation layer as the laser trimming fuse element. There is absolutely no influence due to joining deviations in the wafer processing, and laser trimming can be performed accurately.

Embodiments

Embodiments of the present invention are explained below with reference to the figures.

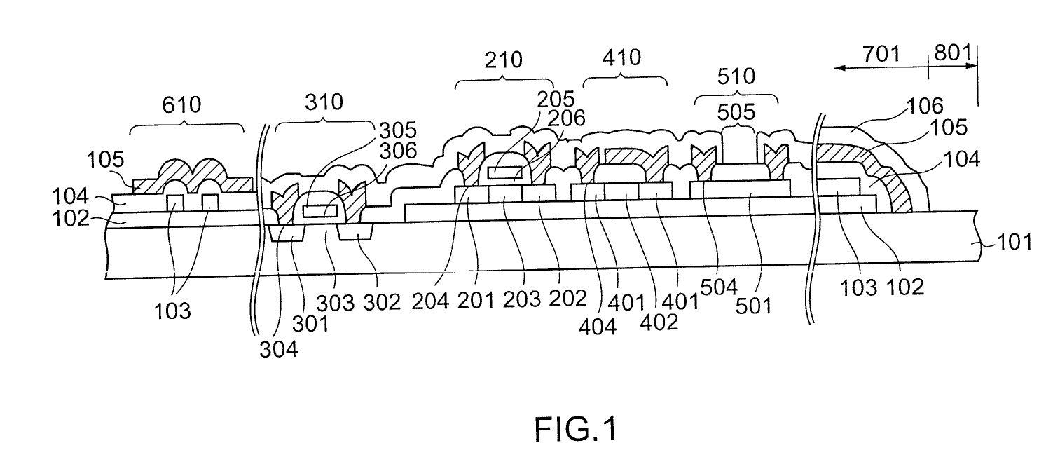

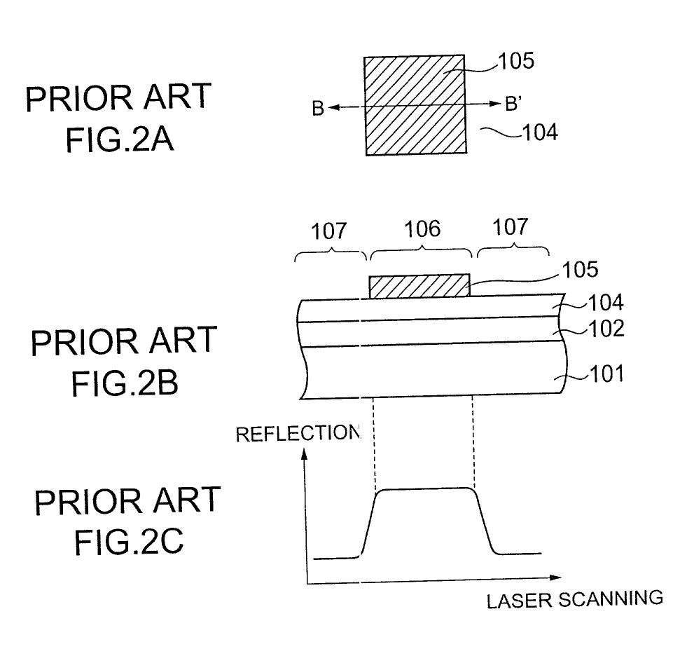

FIG. 1 is a schematic cross sectional diagram of a semiconductor device of the present invention, and an explanation of each region of the semiconductor device is made with reference to FIG. 1.

First, a complete depletion high speed MOS transistor region 210 is explained. A source region 201, a drain region 202, and a channel region 203 are formed within a single crystal silicon device formation layer 103 formed on a silicon substrate 101 through an embedded oxide film 102. In addition, a gate electrode 205 is arranged in an upper portion of the channel region 203 through a gate oxide film 206, forming a MOS transistor. The film thickness of the single crystal silicon device formation layer 103 is set to 500 angstroms, for example, such that complete depletion is made.

An aluminum film 105 is connected to the source region 201 and the drain region 202 through contact holes 204 opened in an intermediate insulating film 104 made from a film such as a BPSG film. A protective film 106 made from a silicon nitride film or the like is then formed in the uppermost layer of the high speed MOS transistor region 210.

The electric potential of the channel region 203 may be left floating, and it may also be fixed, depending upon the circumstances. Further, with an eye to lowered capacitance, it is preferable to form the source region 201 and the drain region 202 so that their bottom areas contact the embedded oxide film 102. The source region 201 and the drain region 202 may be formed having a thickness such that the depleted layer contacts the embedded oxide film 102 when a voltage is applied and formed separated from the embedded oxide film 102.

A high endurance MOS transistor and an ESD protecting circuit region 310 are explained next.

A source region 301, a drain region 302, and a channel region 303 are formed on the silicon substrate 101. A gate electrode 305 is arranged in an upper portion of the channel region 303 through a gate oxide film 306, forming a MOS transistor.

In addition, the aluminum film 105 contacts the source region 301 and the drain region 302 through contact holes 304 opened in the intermediate insulating film 104 made from the film such as the BPSG film. The protective film 106 made from the film such as the silicon nitride film is then formed in the uppermost layer of the high endurance MOS transistor and the ESD protecting circuit region 310, similar to the high speed MOS transistor region 210.

The single crystal silicon device formation layer 103 and the embedded oxide film 102 are removed in the high endurance MOS transistor and the ESD protecting circuit region 310, differing from the high speed MOS transistor region 210, and elements are formed directly on the silicon substrate 101. Although not shown in particular in the figures, high endurance MOS transistors suitable for high operation voltage by using DDD structures, locks drain structures, or the like can be easily formed. Further, the gate oxide film 306 may be formed thicker than the gate oxide film 206 of the high speed MOS transistor region 210. Additionally, although also not shown in the figures for the ESD protecting circuits, off transistors, diodes, and the like possessing thermal capacitance and junction surfaces which are sufficiently capable of withstanding ESD can be formed by being constructed on the silicon substrate 101.

A breeder resistor region 410 is explained next.

A low concentration impurity region 402 sandwiched by a pair of high concentration impurity regions 401 is formed within the single crystal silicon device formation layer 103 formed on the silicon substrate 101 through the embedded oxide film 102. This forms a resistor. Only one resistor is shown in the figures here for simplicity, but in practice, a breeder resistor is formed by a plurality of resistors.

In addition, the aluminum film 105 is connected to the high concentration impurity regions 401 through contact holes 404 opened in the intermediate insulating film 104 made from the film such as the BPSG film. The aluminum film 105 connected to one of the high concentration impurity regions 401 is arranged so as to cover the low concentration impurity region 402 that determines the resistance value of the resistor, which is for attaining a stable resistance value.

This is because changes in the resistance value of the resistor are prevented by the electric potential difference between the conductor adjacent to the resistor and the resistor itself. The electric potential of the aluminum film 105 on the upper portion of the resistor is not a power source electric potential and is not a ground electric potential, but rather is set so as to be the electric potential of one end of the breeder resistor. If all of the plurality of resistors forming the breeder resistor are manufactured similarly, then the electric potential difference between the aluminum film 105, which is arranged on the upper portion of each of the resistors, and the resistors themselves becomes almost zero. The respective resistors produced having the same dimensional shape thus show the same resistance values. High voltage division with high precision thus becomes possible by forming the breeder resistor circuit using these resistors.

Further, compared to a conventional breeder resistor formed by a polycrystalline silicon thin film, the resistors are formed by the single crystal silicon device formation layer 103 itself in the present invention. Therefore, the influence of the grain in the polycrystalline silicon thin film can be eliminated, and very uniform resistors can be obtained. It thus becomes possible to form a higher precision breeder resistor circuit. In addition, the film thickness of the single crystal silicon device formation layer 103 is thin at approximately 500 angstroms for the above-described complete depletion, and therefore thermal variations of the resistance values can be made small.

A case where the resistors having high resistance values are formed in which the low concentration impurity region 402 sandwiched by the pair of high concentration impurity regions 401 is formed is explained. However, if high resistance values are not necessary, then the entire resistors may also be formed only by the high concentration impurity region 401.

The protective film 106 made from the film such as the silicon nitride film is formed in the uppermost layer of the breeder resistor region 410.

A fuse region 510 is explained next. A polycrystalline silicon fuse 502 made from a polycrystalline silicon film 503 is formed on the silicon substrate 101 through the embedded oxide film 102.

The polycrystalline silicon fuse 502 is given good conductivity, and has a high impurity concentration in order to reduce resistance value as much as possible.

The polycrystalline silicon fuse 502 is formed by the same film as the gate electrode 205 of the high speed MOS transistor region 210, and the gate electrode 305 of the high endurance MOS transistor and ESD protecting circuit region 310, and therefore the process of manufacturing can be simplified.

The aluminum film 105 is connected to both ends of the polycrystalline silicon fuse 502 through contact holes 504 opened in the intermediate insulating film 104 made from the film such as the BPSG film. The protective film 106 made from the film such as the silicon nitride film and formed in the uppermost layer of the fuse region 510 is removed in portions touching a laser irradiation region 505. This is done in order to prevent a hindrance in cutting the polycrystalline silicon fuse 502 by such that the energy of the laser beam irradiated in laser trimming is absorbed by the protective film 106.

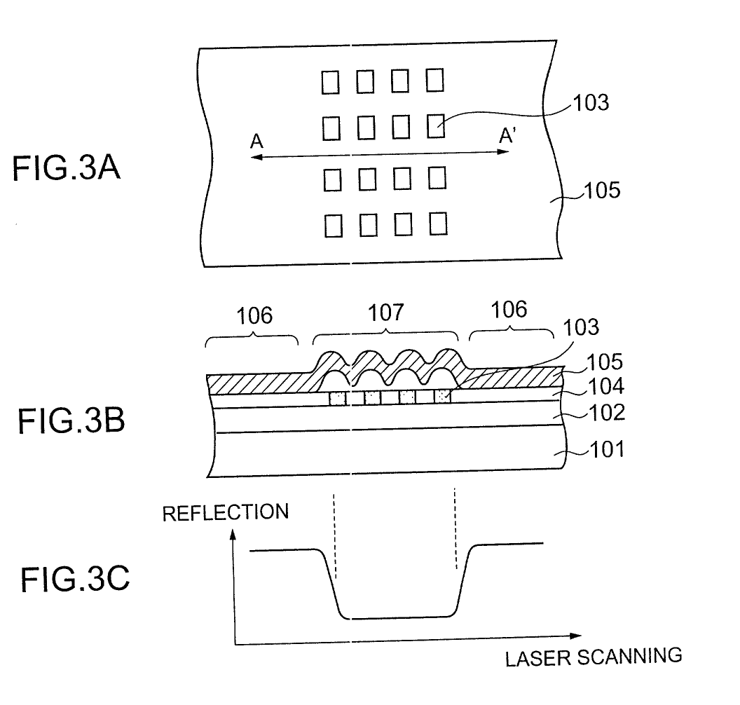

A pattern region 610 used for determining laser trimming positions is explained next. The explanation proceeds with reference to FIGS. 3A to 3C in addition to FIG. 1.

FIG. 3A is a planar diagram of a pattern used for determining the position of a semiconductor device of the present invention, FIG. 3B is a cross sectional diagram of the pattern used for determining the position of the semiconductor device of the present invention, and FIG. 3C is a diagram showing variations in the amount of light reflected when a light beam is scanned to the pattern used for determining the position of the semiconductor device of the present invention. The amount of reflected light is the value for a case of scanning along the direction of the line segment A-A′ of FIG. 3A.

As shown in FIG. 3B, the position determining pattern is structured by the high light reflectivity region 106, and the low light reflectivity region 107 on the inside of the high light reflectivity region, with the present invention.

The structure of the position determining pattern of the present invention is explained using FIGS. 3A and 3B.

The embedded oxide film 102 is formed on the silicon substrate 101, and the polycrystalline silicon film 503 is formed partially in a dot shape on the embedded oxide film 102. The level embedded oxide film 102 is exposed in regions in which the polycrystalline silicon film 503 is not formed, and the intermediate insulating film 104 made from the film such as the BPSG film is formed thereon. The aluminum film 105 is formed on the intermediate insulating film 104. The surface of the aluminum film 105 positioned on regions in which the doted shape polycrystalline silicon film 503 is formed is uneven due to the influence of the pattern of the polycrystalline silicon film 503, and light irradiated to these portions is diffusely reflected. These regions can therefore be made into low light reflectivity regions 107. On the other hand, the surface of the aluminum film 105 formed on regions in which the polycrystalline silicon film 503 is not formed is level, and these regions can be made into the high light reflectivity regions 106.

The amount of light reflected when a light beam is scanned along the direction of the line segment A-A′ of FIG. 3A becomes large in the high light reflectivity region 106 formed by the aluminum film 105 having a level surface, and becomes small in the low light reflectivity region 107 formed by the aluminum film 105 having an uneven surface, as shown in FIG. 3C.

The low light reflectivity region 107 is formed by utilizing the action of light diffused reflection in the example of FIGS. 3A to 3C. The dot shape pattern is formed by the polycrystalline silicon film 503, the same thin film as the polycrystalline silicon fuse 502, in order to make light reflect diffusely. It is also possible to make light reflect diffusely by using a pattern other than the dot shape, such as a lattice shape or a stripe shape, and a light reflection pattern like that shown in FIG. 3C can be obtained.

It is not always necessary to form the intermediate insulating film 104 in FIG. 3B, and therefore it may be removed depending upon the circumstances. Further, a metal material such as tungsten, chromium, or gold may also be used for the high light reflectivity film as a substitute for the aluminum film 105.

As discussed above, the interface between the high light reflectivity region 106 and the low light reflectivity region 107 is determined by the pattern of the polycrystalline silicon film 503, the same film as the polycrystalline silicon fuse 502. Therefore the problem with conventional position determining patterns, namely the problem of joining deviations between the polycrystalline silicon forming the fuse elements, and the aluminum film forming the position determining pattern, can be overcome.

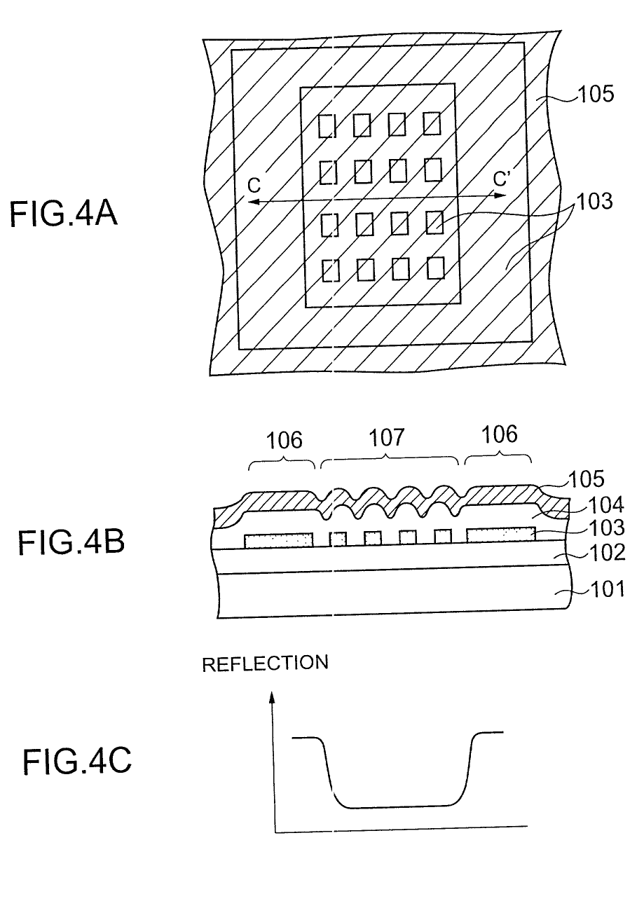

FIG. 4A is a planar diagram of a pattern used in determining position in a second embodiment of a semiconductor device of the present invention, FIG. 4B is a cross sectional diagram of the pattern used in determining position in the second embodiment of the semiconductor device of the present invention, and FIG. 4C is a diagram showing variations in the amount of light reflected when a light beam is scanned in the position determining pattern in the second embodiment of the semiconductor device of the present invention. The amount of reflected light is the value when the light beam is scanned along the direction of a line segment C-C′ in FIG. 4A. The position determining pattern of the second embodiment of the present invention is structured by the high light reflectivity region 106 and the low light reflectivity region 107, which is formed on the inside of the high light reflectivity region 106, similar to the first embodiment shown by FIGS. 3A to 3C.

Differing from the first embodiment is the point that the high light reflectivity region 106 is formed by the aluminum film 105 positioned on the level polycrystalline silicon film 503. Provided that the high light reflectivity region 106 is formed from a high light reflectivity film on a level base, it is can fulfill its role. Therefore, such a structure is possible. Additional explanations are performed using reference symbols identical to those of FIGS. 3A to 3C.

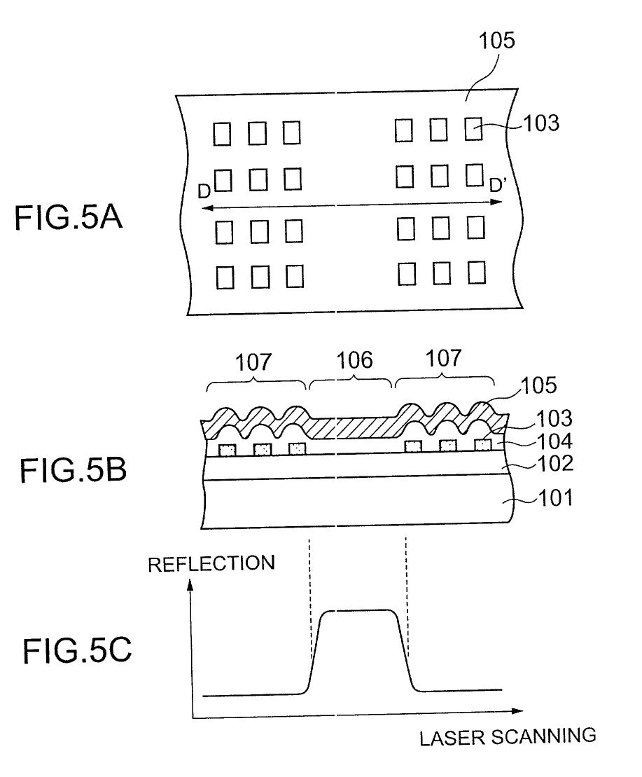

FIG. 5A is a planar diagram of a pattern used in determining position in a third embodiment of a semiconductor device of the present invention, FIG. 5B is a cross sectional diagram of the pattern used in determining position in the third embodiment of the semiconductor device of the present invention, and FIG. 5C is a diagram showing variations in the amount of light reflected when a light beam is scanned in the position determining pattern in the third embodiment of the semiconductor device of the present invention. The amount of reflected light is the value when the light beam is scanned along the direction of a line segment D-D′ in FIG. 5A. The position determining pattern of the third embodiment of the present invention is structured by the low light reflectivity region 107 on the outside and the high light reflectivity region 106 arranged on the inside. Regarding the position determining pattern, one of the high light reflectivity region 106 and the low light reflectivity region 107 may be sandwiched by the other region. The third embodiment shown in FIGS. 5A to 5C shows a case in which the arrangement is the opposite to that of the first embodiment shown in FIGS. 3A to 3C, and shows that this type of structure may also be used. Additional explanations are performed using reference symbols identical to those of FIGS. 3A to 3C.

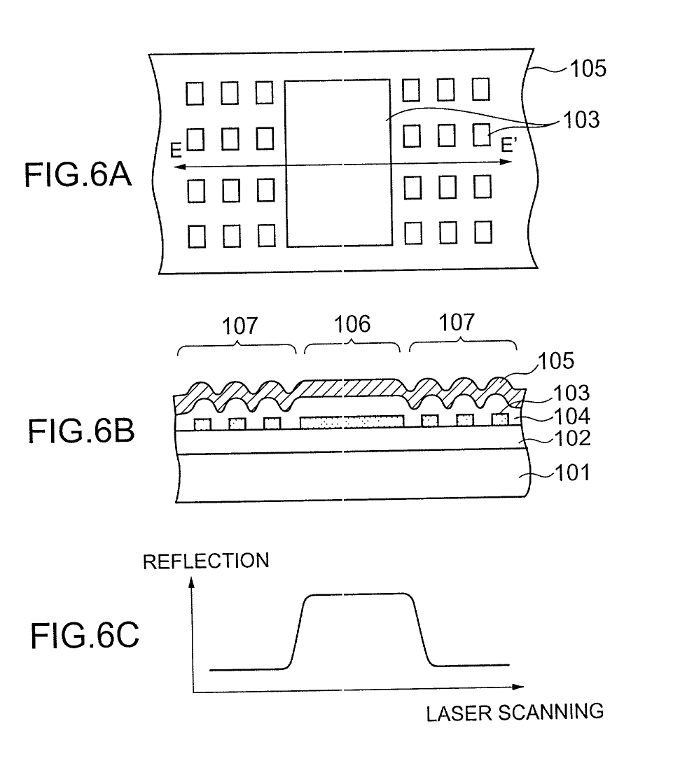

FIG. 6A is a planar diagram of a pattern used in determining position in a fourth embodiment of a semiconductor device of the present invention, FIG. 6B is a cross sectional diagram of the pattern used in determining position in the fourth embodiment of the semiconductor device of the present invention, and FIG. 6C is a diagram showing variations in the amount of light reflected when a light beam is scanned in the position determining pattern in the fourth embodiment of the semiconductor device of the present invention. The amount of reflected light is the value when the light beam is scanned along the direction of a line segment E-E′ in FIG. 6A. The position determining pattern of the fourth embodiment of the present invention is structured by the low light reflectivity region 107 arranged on the outside and the high light reflectivity region 106 arranged on the inside of the low light reflectivity region 107.

Similar to the third embodiment, regarding the position determining pattern, one of the high light reflectivity region 106 and the low light reflectivity region 107 may be sandwiched by the other region, and the fourth embodiment shown in FIGS. 6A to 6C shows a case which the position determining pattern is opposite to that of the second embodiment. Additional explanations are performed using reference symbols identical to those of FIGS. 3A to 3C.

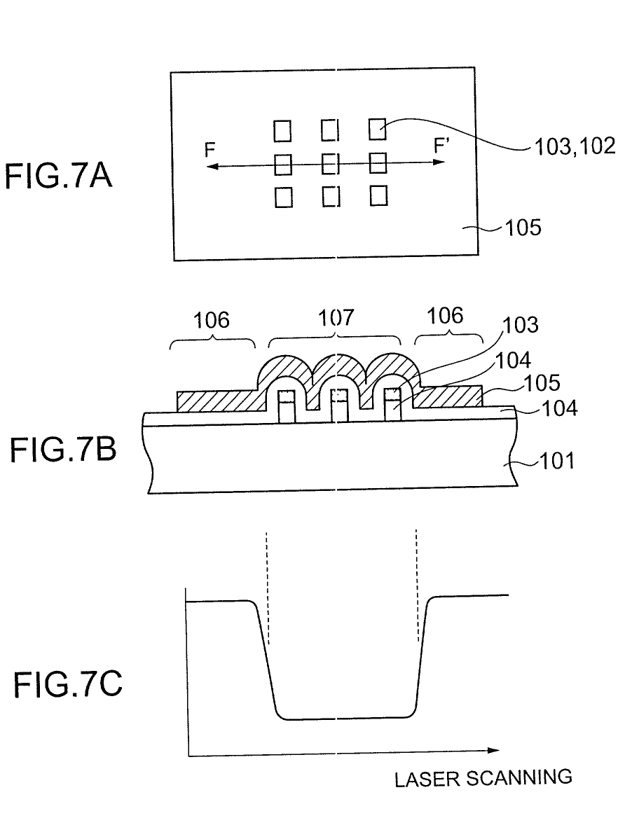

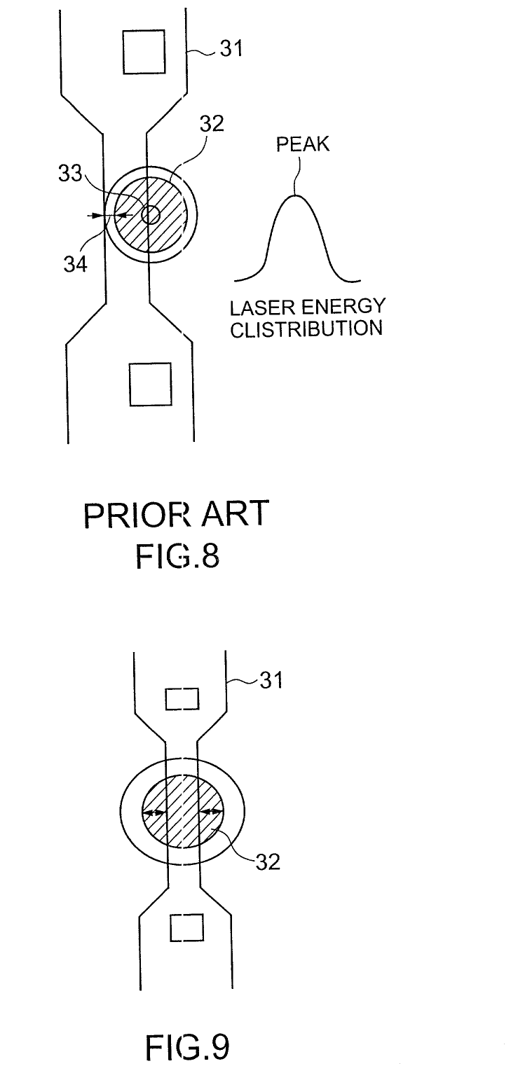

FIG. 7A is a planar diagram of a pattern used in determining position in a fifth embodiment of a semiconductor device of the present invention, FIG. 7B is a cross sectional diagram of the pattern used in determining position in the fifth embodiment of the semiconductor device of the present invention, and FIG. 7C is a diagram showing variations in the amount of light reflected when a light beam is scanned in the position determining pattern in the fifth embodiment of the semiconductor device of the present invention. The amount of reflected light is the value when the light beam is scanned along the direction of a line segment F-F′ in FIG. 7A.

The embedded oxide film 102 and the dot shape polycrystalline silicon film 503 are formed by matching their shapes in the fifth embodiment of the present invention. Dots are formed by a composite film of the polycrystalline silicon film 503 and the embedded oxide film 102, and therefore the height of the dots is higher compared to the dots of the first embodiment. The roughness of the surface of the aluminum film 105 arranged above the regions in which the polycrystalline silicon film 503 is formed also becomes larger. Light irradiated to these portions therefore has a higher degree of diffused reflection compared to the first embodiment, and the reflectivity of light is further decreased.

The amount of reflected light when a light beam is scanned along the direction of the line segment F-F′ of FIG. 7A becomes larger in the high light reflectivity region 106 formed by the aluminum film 105 having a level surface, and becomes smaller in the low light reflectivity region 107 formed by the aluminum film 105 having a rough surface.

The height of the dots is increased because the dots are formed by the composite film of the polycrystalline silicon film 503 and the embedded oxide film 102. The light reflectivity of the low light reflectivity region 107 can be reduced, and therefore the difference in light reflectivity (contrast) with the high light reflectivity region 106 becomes larger. Thus, it is more difficult for disturbances due to external causes to occur during position determination by laser scanning, and very accurate position determination can be performed.

Note that although an example in which the height of the dots is increased based on the first embodiment is shown in the fifth embodiment, it is also possible and effective to similarly increase the height of the dots in the second to fourth embodiments. Further, a similar effect can also be obtained with stripe shapes and lattice shapes, in addition to the dot shapes.

Additional explanations are performed using reference symbols identical to those of FIGS. 3A to 3C.

FIG. 9 is a planar diagram of a fuse element which is being laser trimmed using a position determining pattern of a semiconductor device of the present invention. It becomes possible to irradiate a laser spot 32 to the center of a fuse element 31.

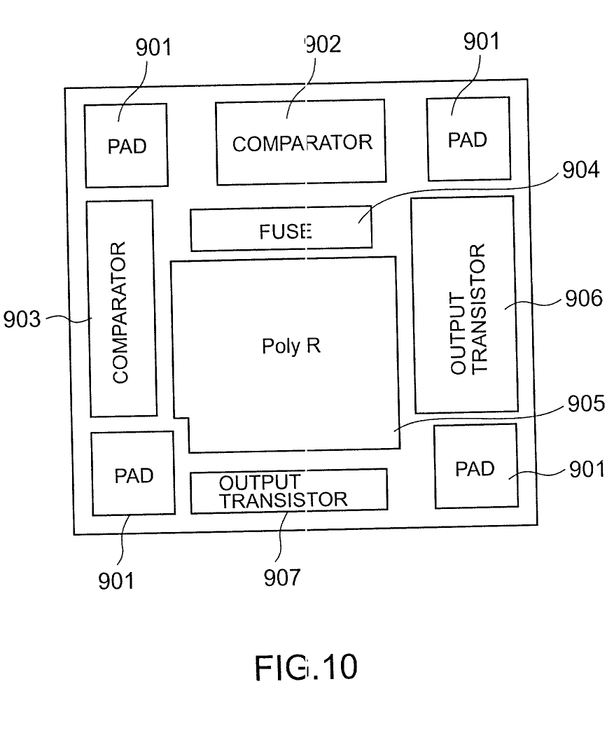

The semiconductor device of the present invention is extremely suitable for semiconductor integrated circuits constituted of semiconductor elements having large dispersion. For example, FIG. 10 is a block diagram of a voltage detection IC containing high endurance MOS transistors. The voltage detection IC comprises four PADs 901 in the corner, comparator 902, 903, fuse 904, output transistor 906, 907, and poly silicon resistor 905. MOS ICs have large dispersion of analog properties compared to bipolar ICs. In particular, the dispersion in analog properties becomes even larger because the film thickness of the gate insulating film is increased for the high endurance case. Therefore, in the case of the analog MOS ICs, it is necessary to have large fuse element regions like that shown in FIG. 10. By forming 10 or more fuse elements, analog properties having little dispersion can be obtained.

Fuse elements can be made smaller by using the position determining pattern of the present invention. In addition, by varying the direction of the fuse elements within a plane, it becomes possible to arrange them in two or more locations.

The position determining pattern of the present invention can also be implemented by being formed within scribe lines, within semiconductor chips, or within TEG chips. Arranging the position determining pattern within the scribe lines or the TEG chips is effective in reducing the semiconductor chip surface area.

Further, although the present invention is applied to the analog MOS ICs, it can also be applied to digital ICs. The present invention is also suitable for the realization of high density analog bipolar ICs having extremely little dispersion. It is not always necessary to form the intermediate insulating film 104 in FIGS. 3A to 7C used in order to explain the laser trimming position determining pattern region 610. Therefore, the intermediate insulating film 104 may be removed depending upon the circumstances. Further, a metallic material such as tungsten, chromium, or gold may also be used as a high light reflectivity film as a substitute for the aluminum film 105.

A scribe region 801 is explained next.

Portions in FIG. 1, which become cutoff in a later dicing process (a process of cutting out IC chips), are scribing regions 801. The scribe region 801 has a shape which begins from the edge of a region 701 on the inside of the semiconductor integrated circuit. The single crystal silicon device formation layer 103 and the embedded oxide film 102 are removed in the scribe region 801 here. The intermediate insulating film 104, the aluminum film 105, the protective film 106 and the like may also be desirably removed as shown in FIG. 1.

This is for preventing the following. If the scribe region 801, which becomes the cut off portion in the dicing process, and the region 701 within the semiconductor integrated circuit are connected by the continuous single crystal silicon device formation layer 103, then cracks and fragmentation may propagate in the region 701 within the semiconductor integrated circuit when a force to impart damage such as cracks, fragmentation, and the like works. As a result, the very important IC chips may be broken, or operational irregularities may occur.

In particular, ICs manufactured on SIO substrates have the thin embedded oxide film 102 and the single crystal silicon device formation layer 103. Therefore, cracks and fragmentation in the embedded oxide film 102 and the single crystal silicon device formation layer 103, which are the upper layers, easily occur, and it is necessary to pay attention to this.

Leaving no continuity of the same film between the scribe region 801, which is cut off in the dicing process, and the region 701 within the semiconductor integrated circuit that becomes the IC chip is an important point in the prevention of cracks and fragmentation of the IC chip. In particular, it is necessary to remove the single crystal silicon device formation layer 103 and the embedded oxide film 102 in the scribe region 801 for ICs formed on SOI substrates, as shown in FIG. 1. In addition, films such as the intermediate insulating film 104, the aluminum film 105, the protective film 106 and the like may also be desirably removed as shown in FIG. 1. Furthermore, for cases where it is necessary to form marks, test patterns, and the like in the scribe region 801, the portion in which the above films are removed is provided between the scribe region 801 and the region 701 within the semiconductor integrated circuit, so that there is no bridging of the scribe region 801 and the region 701 within the semiconductor integrated circuit by continuity of the same film.

The laser trimming fuse element; the laser trimming position determining pattern; the complete depletion high speed MOS transistor; the high endurance MOS transistor; the ESD protecting element; and the breeder resistor formed by the plurality of resistors are formed in the semiconductor integrated circuit constructed on the SOI substrate in the present invention.

The laser trimming position determining pattern is constituted of the region having high light reflectivity and the region having low light reflectivity. The high light reflectivity region is formed by the high light reflectivity film on the level base, and the low light reflectivity region is formed by the high light reflectivity film formed on the lattice pattern, the stripe pattern, or the dot pattern for diffused reflection of light, which is formed of the same thin film as the laser trimming fuse element.

Further, the laser trimming fuse element and the laser trimming position determining pattern are formed from the polycrystalline silicon film, the same material as the gate electrodes of the complete depletion high speed MOS transistor and the high endurance MOS transistor. The breeder resister is formed by the single crystal silicon device formation layer.

In addition, the complete depletion high speed MOS transistor is formed in the single crystal silicon device formation layer, and the high endurance MOS transistor and the ESD protecting element are formed on the silicon substrate remaining after the single crystal silicon device formation layer and the embedded oxide film are removed from the SOI substrate.

On the other hand, the scribe region of the semiconductor integrated circuit takes a structure in which the single crystal silicon device formation layer and the embedded oxide film are removed.

The semiconductor device, in which the high precision analog ICs having a mixture of the complete depletion high speed MOS transistors and the high endurance MOS transistors are formed on the SOI substrate, and which is strong with respect to ESD destruction, with a form in which the factors such as cracks and fragmentation in the dicing process are prevented, can thus be provided.

In particular, the pattern used for determining the laser trimming position is constituted of the region with high light reflectivity and the region with low light reflectivity. The high light reflectivity region is formed by the high light reflectivity film formed on the level base, while the low light reflectivity region is formed by the high light reflectivity film formed on the lattice pattern, the stripe pattern, or the dot pattern for diffused reflection of light, which is formed of the same thin film as the laser trimming fuse element. The interface between the high light reflectivity region and the low light reflectivity region, namely, the location at which the light reflectivity changes suddenly, is therefore prescribed by the pattern formed by the same polycrystalline silicon film as the laser trimming fuse element. Thus, laser trimming can be performed accurately with absolutely no influence due to joining deviations during wafer processing.

What is claimed is:

1. A semiconductor device comprising:
an SOI substrate; and
a semiconductor integrated circuit formed on the SOI substrate, having:
a laser trimming fuse element;
a laser trimming position determining pattern;
a complete depletion high speed MOS transistor;
a high endurance MOS transistor;
an ESD protecting element; and
a breeder resistor formed by a plurality of resistors.

2. A semiconductor device according to claim 1, wherein:
the laser trimming position determining pattern is constituted of a region having high light reflectivity and a region having low light reflectivity;
the high light reflectivity region is formed by a high light reflectivity film on a level base; and
the low light reflectivity region is formed by the high light reflectivity film formed on a lattice pattern, a stripe pattern, or a dot pattern for diffused reflection of light, which is structured by the same thin film as the laser trimming fuse element.

3. A semiconductor device according to claim 1, wherein the laser trimming fuse element is formed of a polycrystalline silicon film.

4. A semiconductor device according to claim 1, wherein a polycrystalline silicon film forming the laser trimming fuse element is the same film as a gate electrode of the complete depletion high speed MOS transistor and a gate electrode of the high endurance MOS transistor.

5. A semiconductor device according to claim 1, wherein:
the complete depletion high speed MOS transistor is formed in a single crystal silicon device formation layer; and
the high endurance MOS transistor and the ESD protecting element are formed on a silicon substrate remaining after the single crystal silicon device formation layer and an embedded oxide film are removed from the SOI substrate.

6. A semiconductor device according to claim 1, wherein the breeder resistor is formed by the single crystal silicon device formation layer.

7. A semiconductor device according to claim 1, where in a single crystal silicon device formation layer and an embedded oxide film are removed in scribe regions of the semiconductor integrated circuit.
